(19) United States
(12) Patent Application Publication
(10) Pub. No.: US 2024/0373751 A1
(43) Pub. Date: Nov. 7, 2024

(54) Energy Harvester and Method for Manufacturing an Energy Harvester

(71) Applicant: Tegnology ApS, Søborg (DK)

(72) Inventor: Hao Yin, Søborg (DK)

(21) Appl. No.: 18/686,963

(22) PCT Filed: Aug. 31, 2022
(86) PCT No.: PCT/EP2022/074193

§ 371 Date: Feb. 27, 2024

(30) Foreign Application Priority Data
Aug. 31, 2021 (DK) PA202170434

(51) Int. Cl. H10N 10/01; H10N 10/17

(52) U.S. Cl. CPC H10N 10/01; H10N 10/17

(57) ABSTRACT

Methods of manufacturing an energy harvester and an energy harvester for converting thermal energy into electric energy are described. The energy harvester includes an electrically conductive and flexible substrate, a plurality of thermoelectric legs, and an opposite electrode layer. Bonding of the substrate to the opposite electrode layer provides a serial electrical connection of alternating N-type thermoelectric legs and P-type thermoelectric legs.

### CROSS-REFERENCE TO RELATED APPLICATIONS

This application is the national phase of, and claims priority to, International Application No. PCT/EP2022/074193, filed Aug. 31, 2022, which claims priority to Denmark Application No. PA 2021 70434, filed Aug. 31, 2021.

### FIELD OF THE INVENTION

The invention relates to a method for manufacturing an energy harvester for converting thermal energy into electric energy, and an energy harvester for converting thermal energy into electric energy.

### BACKGROUND

Thermoelectric devices have steadily been gaining traction as viable energy sources for sensors and other internet-of-things (IoT) devices. A thermoelectric device is formed from alternating N and P elements/legs made of semiconducting material. The thermoelectric legs are placed on a substrate and another substrate is arranged on top to connect the thermoelectric legs in series with each other.

An electrical current may be created by the thermoelectric device by the Seebeck effect, where a temperature difference over the thermoelectric device leads to a current being created by the alternating N and P elements/leg.

U.S. Pat. No. 10,553,773 B2 discloses a method of encapsulating a thin-film based thermoelectric module which includes forming the thin-film based thermoelectric module by sputter depositing pairs of N-type thermoelectric legs and P-type thermoelectric legs electrically in contact with one another on a flexible substrate having a dimensional thickness less than or equal to 25 μm, and rendering the formed thin-film based thermoelectric module flexible and less than or equal to 100 μm in dimensional thickness based on choices of fabrication processes with respect to layers of the formed thin-film based thermoelectric module. The method also includes encapsulating the formed thin-film based thermoelectric module with an elastomer to render the flexibility thereto. The elastomer encapsulation has a dimensional thickness less than or equal to 15 μm, and the flexibility enables an array of thin-film based thermoelectric modules to be completely wrappable and bendable around a system element from which the array is configured to derive thermoelectric power.

In certain applications, ceramic enclosure(s) may encapsulate the aforementioned thermoelectric device. However, a traditional implementation of the thermoelectric device may be limited in application thereof because of rigidity, bulkiness, size and high costs associated therewith. In addition, the ceramic enclosure(s) and the substrate rigidity may compromise flexibility of the thermoelectric device.

### SUMMARY

It is an object of the invention to overcome these problems, and to provide an improved energy harvester, which overcomes or at least alleviates the problems highlighted in the prior art.

According to a first aspect of the invention, this and other objects are achieved by a method of manufacturing an energy harvester, the method comprising the steps of:
providing an electrically conductive and flexible substrate having a substrate surface,
providing a plurality of thermoelectric legs each having a substrate end and an opposite end, the plurality of thermoelectric legs comprising N-type thermoelectric legs and P-type thermoelectric legs,
arranging the substrate ends of the plurality of thermoelectric legs on the substrate surface,
bonding the substrate ends of the plurality of thermoelectric legs to the substrate to form a plurality of pairs of neighbouring thermoelectric legs, with each pair of neighbouring thermoelectric legs having an N-type thermoelectric leg being electrically connected to a P-type thermoelectric leg via the substrate ends of the N-type thermoelectric leg and the P-type thermoelectric leg,
providing an opposite electrode layer with an opposite electrode layer surface,
arranging the opposite electrode layer on the opposite ends of the plurality of thermoelectric legs,
bonding the opposite ends of the plurality of thermoelectric legs to the opposite electrode layer surface, and
separating the opposite electrode layer into several segments to electrically connect pairs of neighbouring N-type thermoelectric legs and P-type thermoelectric legs, thereby forming serial electrical connections between pairs of neighbouring thermoelectric legs.

Consequently, a simple and efficient method for manufacturing an energy harvester is achieved. The simple manufacturing method allows for the manufacturing of the energy harvester to be compatible with manufacturing facilities used within the electronics industry, hence facilitating upscaling in production of the energy harvester, and cheaper manufacturing of the energy harvester.

The energy harvester manufactured in the method comprises serially connected pairs of neighbouring N-type thermoelectric legs and P-type thermoelectric legs. Thus, the energy harvester may be considered to have a series of alternating N-type thermoelectric legs and P-type thermoelectric legs. In general, the substrate end of an N-type thermoelectric leg is electrically connected to the substrate end of a P-type thermoelectric leg, and the opposite end of the N-type thermoelectric leg is electrically connected to the opposite end of another P-type thermoelectric leg than the N-type thermoelectric leg is electrically connected to via its substrate end.

In the energy harvester the plurality of thermoelectric legs is arranged on the substrate surface with the substrate end of an N-type thermoelectric leg being electrically connected to the substrate end of a P-type thermoelectric leg, and the electrically connected N-type and P-type type thermoelectric legs are considered be a pair of neighbouring thermoelectric legs, e.g. a pair of a neighbouring N-type thermoelectric leg and a P-type thermoelectric leg. Correspondingly, an N-type thermoelectric leg electrically connected to a P-type thermoelectric leg via the opposite ends of the thermoelectric legs is likewise considered to be a pair of neighbouring thermoelectric legs, e.g. a pair of a neighbouring N-type thermoelectric leg and a P-type thermoelectric leg. In the present context, a pair of neighbouring thermoelectric legs may be described in relation to the ends of the thermoelectric legs. Thus, a pair of neighbouring thermoelectric legs may be a substrate end pair of neighbouring thermoelectric legs, or a pair of neighbouring thermoelectric legs may be an opposite end pair of neighbouring thermoelectric legs. When a pair of neighbouring thermoelectric legs is mentioned without specifying the relevant end of the thermoelectric legs, the end may be either the substrate end or the opposite end, and the relevant end is evident from the context.

In general, an N-type thermoelectric leg and a P-type thermoelectric leg of a pair of neighbouring thermoelectric legs are adjacent to each other. However, the N-type thermoelectric leg is not limited to be adjacent to the P-type thermoelectric leg to represent a pair of neighbouring thermoelectric legs, as the electrical connections between the ends of the thermoelectric legs define the thermoelectric legs to be a pair of neighbouring thermoelectric legs.

The opposite electrode layer is arranged on the opposite ends of the plurality of neighbouring thermoelectric legs, and subsequently the opposite ends of the plurality of thermoelectric legs are bonded to the opposite electrode layer surface. The substrate ends of the plurality of thermoelectric legs are arranged on the substrate surface and thereby the opposite ends of the plurality of thermoelectric legs can be considered to extend from the substrate surface allowing the opposite electrode layer to be arranged on the opposite ends of the plurality of thermoelectric legs. In general, the opposite electrode layer has a size sufficient for the opposite electrode layer to be arranged on several pairs of neighbouring N-type thermoelectric legs and P-type thermoelectric legs. For example, the opposite electrode layer may be arranged on all thermoelectric legs of an energy harvester, so that the method employs a single opposite electrode layer, e.g. for a single energy harvester. However, it is also contemplated that the method may employ more than one opposite electrode layer for one energy harvester, where each opposite electrode layer is arranged on the opposite electrode layer on the opposite ends of a plurality of neighbouring thermoelectric legs.

After bonding the opposite ends of the plurality of thermoelectric legs to the opposite electrode layer surface, the opposite electrode layer is separated into segments, e.g. into several segments, to electrically connect pairs of neighbouring N-type thermoelectric legs and P-type thermoelectric legs, thereby forming serial electrical connections between pairs of neighbouring thermoelectric legs. In the present context, a segment comprises a single pair of a neighbouring N-type thermoelectric leg and a P-type thermoelectric leg. Thereby, the opposite end of an N-type thermoelectric leg is electrically connected to the opposite end of a P-type thermoelectric leg. The step of separating the opposite electrode layer into segments may be performed using any procedure, although the step of separating the opposite electrode layer into segments generally involves removing material. Thus, by removing material, an electrical connection via the opposite electrode layer is prevented due to the removal of the material of the opposite electrode layer. The combination of arranging and subsequent bonding of the opposite electrode layer on the opposite ends of the plurality of neighbouring thermoelectric legs with the step of separating the opposite electrode layer into segments provides a greatly simplified manufacture of an energy harvester, in particular compared to a process where individual pieces of electrode material are to be placed on the opposite ends of N-type thermoelectric legs and P-type thermoelectric legs to be electrically connected. For example, since the opposite ends of the plurality of thermoelectric legs can be bonded to the opposite electrode layer surface in a single operation, e.g. by soldering or sintering, without consideration of how the N-type thermoelectric legs and the P-type thermoelectric legs are arranged on the substrate layer with respect to the formation of pairs of neighbouring N-type thermoelectric legs and P-type thermoelectric legs on the substate surface, a more robust manufacturing process is provided.

The step of separating the opposite electrode layer into segments to electrically connect pairs of neighbouring N-type thermoelectric legs and P-type thermoelectric legs may be based on knowledge of the positioning of the pairs of neighbouring N-type thermoelectric legs and P-type thermoelectric legs on the substate surface. An N-type thermoelectric leg may be electrically connected to a P-type thermoelectric leg located anywhere on the substrate surface. For example, after arranging the opposite electrode layer on the opposite ends of the plurality of thermoelectric legs and bonding the opposite ends of the plurality of thermoelectric legs to the opposite electrode layer surface, the opposite electrode layer may be cut, based on the knowledge of the positioning of the pairs of neighbouring N-type thermoelectric legs and P-type thermoelectric legs on the substate surface, to serially electrically connect pairs of neighbouring thermoelectric legs. Thus, the method is especially not limited to require that N-type thermoelectric leg of a pair of neighbouring N-type thermoelectric legs and P-type thermoelectric legs is adjacent to the P-type thermoelectric leg of the pair of neighbouring N-type thermoelectric legs and P-type thermoelectric legs on the substate surface. Thereby, the step of cutting the opposite electrode layer to separate the opposite electrode layer into segments and form serial electrical connections between pairs of neighbouring thermoelectric legs is more flexible than when the serial electrical connections are made using individual pieces of connecting material.

The serial electrical connections formed between pairs of neighbouring thermoelectric legs is not limited to serially connect one P-type thermoelectric leg with one N-type thermoelectric leg, and in particular one P-type thermoelectric leg may be serially connected with more than one N-type thermoelectric leg or one N-type thermoelectric leg may be serially connected with more than one P-type thermoelectric leg. Correspondingly, a group, e.g. a group of 2 to 10, of N-type thermoelectric legs may be serially connected to a group of the same size of P-type thermoelectric legs, and vice versa. For example, the step of separating the opposite electrode layer into segments to electrically connect pairs of neighbouring N-type thermoelectric legs and P-type thermoelectric legs, thereby forming serial electrical connections between pairs of neighbouring thermoelectric legs may be performed, especially by cutting the opposite electrode layer, for one P-type thermoelectric leg to be serially connected with a plurality of N-type thermoelectric legs, e.g. from 2 to 10, such as 2, 3, 4, 5, 6, 7, 8 or 9, N-type thermoelectric legs, or one N-type thermoelectric leg to be serially connected with a plurality of P-type thermoelectric legs, e.g. from 2 to 10, such as 2, 3, 4, 5, 6, 7, 8 or 9, N-type thermoelectric legs, or for a group of 2 to 10, such as 2, 3, 4, 5, 6, 7, 8 or 9, N-type thermoelectric legs to be serially connected with a group of P-type thermoelectric legs, e.g. likewise of 2 to 10, such as 2, 3, 4, 5, 6, 7, 8 or 9 P-type thermoelectric legs. When an N-type thermoelectric leg is serially connected with a plurality of P-type thermoelectric legs, or when a P-type thermoelectric leg is serially connected with a plurality of N-type thermoelectric legs, or when groups of P-type thermoelectric legs are serially connected to groups of N-type thermoelectric legs, the N-type thermoelectric legs and P-type thermoelectric legs are still considered to be pairs of neighbouring N-type thermoelectric legs and P-type thermoelectric legs in the present context. When one N-type thermoelectric leg is serially connected with a plurality of P-type thermoelectric legs, or when a P-type thermoelectric leg is serially connected with a plurality of N-type thermoelectric legs, the number of N-type thermoelectric legs and the number of P-type thermoelectric legs for an energy harvester may be selected to match the ratio between N-type thermoelectric legs to P-type thermoelectric legs and/or the ratio between P-type thermoelectric legs to N-type thermoelectric legs. Due to the serial connection between the N-type thermoelectric legs and P-type thermoelectric legs, there is a risk that a connection between a thermoelectric leg and the opposite layer is broken so that an electrical current cannot flow through the energy harvester. However, when an N-type thermoelectric leg or a group of N-type thermoelectric legs is serially connected with a plurality of P-type thermoelectric legs, or when a P-type thermoelectric or a group of P-type thermoelectric legs is serially connected with a plurality of N-type thermoelectric legs the risk of breakdown of the energy harvester due to the loss of a connection between a thermoelectric leg and the opposite electrode layer is greatly reduced. This is particularly relevant, when the energy harvester does not employ a further layer on the opposite electrode layer. Thus, in an example of the energy harvester the serial electrical connection of alternating N-type thermoelectric legs and P-type thermoelectric legs comprises individual N-type thermoelectric legs serially connected to groups of P-type thermoelectric legs, individual P-type thermoelectric legs serially connected to groups of N-type thermoelectric legs or groups of N-type thermoelectric legs serially connected to groups of P-type thermoelectric legs, and the energy harvester does not comprise a further layer arranged onto the opposite electrode layer opposite the plurality of thermoelectric legs. The groups of either or both of the N-type thermoelectric legs and the P-type thermoelectric legs may comprise 2 to 10, e.g. 4, of the respective type of thermoelectric legs. When the energy harvester of the disclosure includes serial electrical connections involving groups of either or both of the N-type thermoelectric legs and the P-type thermoelectric legs, the step of separating the opposite electrode layer into segments to electrically connect pairs of neighbouring N-type thermoelectric legs and P-type thermoelectric legs is advantageously performed by cutting the opposite electrode layer. From knowledge of the positioning of N-type thermoelectric legs and P-type thermoelectric legs in the substrate, e.g. as prepared in a pick-and-place process, the cutting may be performed to form serial electrical connections between the intended individual or groups of thermoelectric legs, thereby providing a simplified process.

The arrangement of the plurality of thermoelectric legs on top of the substrate surface may be carried out in a plethora of ways. Preferably, the plurality of N-type thermoelectric legs and the plurality of P-type thermoelectric legs are provided as bulk components. Providing the thermoelectric legs as bulk components allows for the thermoelectric legs to be picked up and placed in a desired location on the substrate. The thermoelectric legs may be placed manually by a person or automatically by machinery configured for picking and placing components, e.g. using a pick-and-place process. When the N-type thermoelectric legs and the P-type thermoelectric legs are arranged using automated machinery, the automated machinery will generally map the position of the N-type thermoelectric legs and the P-type thermoelectric legs and how their substrate ends are connected, e.g. with respect to pairs of neighbouring thermoelectric legs. The mapped positions of the N-type thermoelectric legs and the P-type thermoelectric legs can then be used in the step of separating the opposite electrode layer into segments. For example, the pick-and-place process may be used together with cutting, e.g. laser cutting, of the opposite electrode layer.

The step of bonding the thermoelectric legs to the substrate and/or the top electrode may be achieved by providing a bonding agent on the substrate and/or the top electrode. The bonding agent may be placed on the substrate and/or the top electrode before the thermoelectric legs, e.g. by placing the bonding agent on the substrate and/or the top electrode and then contacting the bonding agent with the thermoelectric legs. The bonding agent may be placed on the substrate and/or the top electrode after the thermoelectric legs, e.g. by placing the thermoelectric legs on the substrate and/or the top electrode and then bonding with the bonding agent. The bonding agent may be an adhesive, a solder, or a sintering agent allowing bonding to be accomplished by sintering. Alternatively, bonding may be achieved by welding.

The substrate may comprise a plurality of bonding areas formed on it. The bonding areas may be formed by depositing a bonding agent onto the substrate. The bonding areas may be formed by etching the substrate, e.g. the substrate may comprise a conductive surface with an insulating base layer underneath, thus by etching the conductive surface bonding areas may be formed. The bonding areas may be formed by printing, as is known from printed circuit boards. Each bonding area may be configured for receiving one N-type thermoelectric leg and one neighbouring P-type thermoelectric leg, thus forming a neighbouring pair of an N-type thermoelectric leg and a P-type thermoelectric leg on each bonding area. The bonding areas may be electrically conductive, consequently when the one N-type thermoelectric leg and one P-type thermoelectric leg is arranged on the bonding area, an electrically connected neighbouring pair of an N-type thermoelectric leg and a P-type thermoelectric leg is formed on the bonding area. In a preferred embodiment, the number of bonding areas formed on the substrate is in the range 4 to 1000, preferably 60 to 80.

Forming the serial electrical connections between pairs of neighbouring N-type thermoelectric legs and P-type thermoelectric legs may be carried out by separating the opposite electrode layer into several segments to electrically connect pairs of neighbouring N-type thermoelectric legs and P-type thermoelectric legs in series with each other. The segments may bridge between different pairs of neighbouring N-type thermoelectric legs and P-type thermoelectric legs to connect them in series with each other. The segments of the opposite electrode layer are preferably arranged to extend from an N-type thermoelectric leg of a first neighbouring pair of thermoelectric legs to a P-type thermoelectric leg of a second neighbouring pair of thermoelectric legs. Separating the opposite electrode layer into different segments may be carried out before or after being bonded to the thermoelectric legs, preferably after to reduce the amount pieces required to be handled. Forming of the serial electrical connections, e.g. the step of separating the opposite electrode layer into segments, may be carried out by cutting, etching or melting the opposite electrode layer.

The serial electrical connections between pairs of neighbouring N-type thermoelectric legs and P-type thermoelectric legs may be formed by electrically connecting an N-type thermoelectric leg of a first neighbouring pair of thermoelectric legs to a P-type thermoelectric leg of a second neighbouring pair of thermoelectric legs.

In an embodiment the steps of bonding the plurality of thermoelectric legs to the substrate and/or the opposite electrode layer is carried out by soldering, sintering, or welding. Soldering and sintering are widely used techniques within the production of electronics, thus further elevating the compatibility between the energy harvester according to the invention and existing production techniques used within electronics. Soldering and sintering are especially advantageous when combined with cutting of the opposite electrode layer to separate the opposite electrode layer into segments, as this combination provides a simplified process.

Soldering is preferably used as the bonding technique in situations where the energy harvester is supposed to be used for temperatures below 230° C. Sintering is preferably used as the bonding technique in situations where the energy harvester is supposed to be used for temperatures above 230° C. The sintering may be silver sintering.

Soldering or sintering may be carried out by forming solder pads onto the substrate, each soldering pad being configured for receiving one N-type thermoelectric leg and one P-type thermoelectric leg. The solder pads may be formed with any desired shape. The solder pads may be formed with a general rectangular, or general elliptical shape onto the substrate when viewing the substrate from a top view. The solder pads may be formed with a general rectangular shape with a width in the range of 0.5 mm to 20 mm, preferably 2 mm to 10 mm, and a length in the range of 0.5 mm to 10 mm, preferably 1 to 5 mm. The solder pads may act as bonding areas on the substrate.

In an embodiment the step of forming serial electrical connections between pairs of neighbouring thermoelectric legs comprises cutting the opposite electrode layer. Consequently, forming of the opposite electrode layer is carried out by a readily available method. The cutting may be carried out by laser cutting or blade cutting.

Cutting of the opposite electrode layer may be carried out before the opposite electrode layer is arranged on the thermoelectric legs. However, preferably the opposite electrode layer is arranged on and covering the opposite ends of the thermoelectric legs, then subsequently bonded to the electric legs, and lastly cut to electrically connect the plurality of thermoelectric legs in series with each other. The opposite electrode layer serves to electrically connect pairs of thermoelectric legs formed on the substrate in series.

In an embodiment the step of arranging the plurality of thermoelectric legs on top of the substrate is carried out by a pick-and-place process. Pick-and-place processes and machinery is widely employed within the electronics industry, thus further facilitating the compatibility between the energy harvester and machinery processes already in place within the electronics industry. For the production of an energy harvester the pick-and-place process may be especially advantageous as only surface mounted devices are needed for creating the energy harvester according to the invention. The energy harvester according to the invention may be built-up in layers on the substrate, the built-up of layers being compatible with pick-and-place processes and machinery. This is in contrast to the more traditional through-hole technology, where holes through the substrate are required to place electrical components, where in surface mounted devices placement on top of the substrate suffices.

The combination of bonding the opposite electrode layer to the opposite ends of the plurality of thermoelectric legs and subsequently separating the opposite electrode layer into segments to electrically connect pairs of neighbouring N-type thermoelectric legs and P-type thermoelectric legs by cutting is especially advantageous when also combined with a pick-and-place process for arranging the substrate ends of the plurality of thermoelectric legs on the substrate surface, since this combination greatly simplifies the manufacture of an energy harvester.

In an embodiment the method further comprises the step of arranging an insulating layer onto the opposite electrode layer opposite the plurality of thermoelectric legs. Providing an insulating layer on the opposite electrode layer assures that no unforeseen short circuits happen. An insulating layer on the opposite electrode layer may also be referred to as a top layer. However, it is preferred that no further layers are arranged onto the opposite electrode layer opposite the plurality of thermoelectric legs. When no further layers are arranged onto the opposite electrode layer, the opposite electrode layer may also be referred to as a heat recipient surface. The heat recipient surface is the surface of the energy harvester facing a heat source and the substrate of the energy harvester faces away from any heat source so that the energy harvester can produce electricity from the heat gradient between the opposite electrode layer and the substrate.

In an embodiment an insulating layer is provided on a thermally conductive base layer. The thermally conductive base layer assures good thermal connection to an external environment, thus facilitating a possible increase in the temperature difference over the energy harvester. The thermally conductive base layer may be graphite or other materials with a high thermal conductivity. Furthermore, the thermally conductive base layer may facilitate the opposite electrode layer to act as the warm side of the energy harvester, and the substrate to act as the cold side of the energy harvester.

The insulating layer may be provided as a spray layer on the thermally conductive base layer. The insulating layer may be provided as a Boron Nitride spray onto the thermally conductive base layer.

According to a second aspect of the invention, objects of the invention

are achieved by an energy harvester for converting thermal energy into electric energy, the energy harvester comprising:
an electrically conductive and flexible substrate having a substrate surface,
a plurality of thermoelectric legs each having a substrate end and an opposite end, the thermoelectric legs being arranged on and bonded to the substrate surface by soldering or sintering, and comprising N-type thermoelectric legs and P-type thermoelectric legs, and
an opposite electrode layer arranged on the opposite ends of the plurality of thermoelectric legs and bonded to the plurality of thermoelectric legs by soldering or sintering,
wherein the bonding to the substrate and to the opposite electrode layer provides a serial electrical connection of alternating N-type thermoelectric legs and P-type thermoelectric legs.

The opposite electrode layer may also be referred to as a heat recipient surface. It is preferred that the opposite electrode layer does not comprise further layers.

The substrate may be made from a metallic foil or a metallic cladded sheet of paper or plastic. The substrate may comprise a plurality of materials and/or layers. The substrate may comprise a non-conductive flexible base on top of which electrodes are deposited. Alternatively, the substrate may comprise a base layer cladded with a conductive layer, where the conductive layer is etched away to form the desired electrical connections. Preferably, the substrate comprises a plurality of bonding areas for allowing a plurality of thermoelectric legs to be bonded to the substrate. The plurality of bonding areas may be formed as electrodes, where the electrodes are configured to electrically connect thermoelectric legs arranged on the same electrode. The substrate may be formed with any desired shape, e.g. having a generally rectangular or generally elliptical shape when viewing the substrate from a top view. The substrate may be formed with a box shape. The box shape of the substrate may be formed with any desired dimensions. In a preferred embodiment the box shape is formed with a height in the range of 0.1 mm to 2 mm, a width in the range of 20 mm to 30 mm, and a length in the range of 20 mm to 30 mm. Having a substrate with a small footprint may facilitate the application of the energy harvester for a wide variety of applications, e.g. used in hard to reach and/or space limited areas, the energy harvester may even be arranged as an integrated component in a circuit. During use of the energy harvester the substrate is configured to act as the cold side of the energy harvester.

The material of the thermoelectric legs may be chosen from any thermal electrical material capable of converting a heat difference into an electric current. The material of the thermoelectrical legs may be chosen dependent on the application of the energy harvester. The P-type thermoelectrical legs may comprise one or more of the following thermoelectrical materials: Mg₃Sb₂, ZnSb, Zn₄Sb₃, Bi₂Te₃, PbTe, and SiGe. The N-type thermoelectrical legs may comprise one or more of the following thermoelectrical materials: Mg₃Sb₂, Bi₂Te₃, PbTe, SiGe, and Mg₂SiSn. The thermoelectric legs are preferably formed as rectangular pillars. However, the thermoelectric legs may be formed as pillars with any desired cross-section. The thermoelectric legs may be formed as box-shaped pillars with a width in the range of 0.5 mm to 5 mm, a length in the range of 0.5 mm to 5 mm, and a height in the range of 0.5 mm to 100 mm. The number of thermoelectric legs arranged on the substrate may be chosen dependent on a desired application and power output of the energy harvester. In a preferred embodiment 60 to 80 N-type thermoelectric legs and 60 to 80 P-type thermoelectric legs are arranged on the substrate.

The thermoelectrical legs may comprise a plurality of layers. In a preferred embodiment the thermoelectrical legs comprises a first electrode for electrically connecting the thermoelectrical leg to the substrate, a first barrier layer acting as a diffusion barrier between the first electrode and a thermoelectrical layer, a thermoelectrical layer for generating a current as a result of a temperature difference over the thermoelectrical leg, a second barrier layer acting as a diffusion barrier between a second electrode and the thermoelectrical layer, and the second electrode for electrically connecting the thermoelectrical leg to the opposite electrode layer. The electrodes of the thermoelectrical legs may be made from Ag or Au. The barrier layers may be made from Ti, CrN, Mo, or Ni. The electrodes and/or the barrier layers may be formed on the thermoelectrical layer by physical vapour deposition or other similar sputtering techniques, preferably the electrodes and/or the barrier layers are formed by sputtering outside of a clean room.

The opposite electrode layer may be made from a metallic foil or a metal cladded sheet of paper or plastic. The opposite electrode layer may comprise a plurality of materials and/or layers. The opposite electrode layer may comprise a non-conductive flexible base on which electrodes are deposited. The opposite electrode layer is preferably formed with a shape corresponding to the substrate. Preferably, the opposite electrode layer is formed by a flexible, thin, and conductive layer which is easy to separate into different segments. During use of the energy harvester the opposite electrode layer is configured to act as the warm side of the energy harvester.

In the method of the invention, the opposite electrode layer is separated into segments to electrically connect pairs of neighbouring N-type thermoelectric legs and P-type thermoelectric legs, and correspondingly the energy harvester comprises a segmented surface facing the heat source, e.g. the heat recipient surface. Each segment of the surface, i.e. in the segmented the opposite electrode layer, represents a serial electrical connection of an N-type thermoelectric leg and a P-type thermoelectric leg. The substrate layer is flexible, and due to the segmented surface of the opposite electrode layer where each segment represents a connection between a pair of neighbouring N-type and P-type thermoelectric legs, the opposite electrode layer is also flexible. Thus, the segmented opposite electrode layer increases the flexibility of the energy harvester compared to conventional energy harvesters not having a segmented surface.

In an embodiment the substrate comprises a flexible circuit board (CB). Having the substrate formed by a CB facilitates the compatibility between the energy harvester and other electronic component, and production facilities used within the electronics industry.

The flexible CB may be formed with a flexible base layer such as polyamide, with one or more electrodes deposited on the flexible base layer. The electrodes deposited on the flexible CB may act as bonding areas for the thermoelectric legs. In a preferred embodiment the substrate comprises a flexible printed circuit board (PCB).

In an embodiment the opposite electrode layer comprises an electrically conductive foil, preferably with a thickness in the range of 1 μm to 500 μm. For example, the electrically conductive foil, e.g. a metal foil, may have a thickness in the range of 10 μm to 500 μm, e.g. 50 μm to 400 μm, or 100 μm to 200 μm.

Consequently, a flexible, electrically conductive and cuttable material is provided for the opposite electrode layer. Furthermore, the electrically conductive foil may exhibit a sagging behaviour between the thermoelectric legs, i.e. when the foil is arranged on the thermo electric legs, the foil may start to sag in-between the legs. The sagging behaviour may be advantageous in further improving the flexibility of the energy harvester, as the opposite electrode layer will allow for a larger degree of bending of the energy harvester before the opposite electrode layer is strained or even snaps.

The electrically conductive foil may be a metallic foil, e.g. an Ag-foil, an Au-foil, a Cu-foil, an Al-foil, or a Fe-foil.

In an embodiment the energy harvester is obtainable by a method of manufacture according to the first aspect of the invention.

It is noted that the invention relates to all possible combinations of features recited in the claims. Other objectives, features, and advantages of the inventive concept will appear from the following detailed disclosure, from the attached claims as well as from the drawings. A feature described in relation to one of the aspects may also be incorporated in the other aspect, and the advantage of the feature is applicable to all aspects in which it is incorporated.

### BRIEF DESCRIPTION OF THE DRAWINGS

In the following, the invention will be explained in greater detail with the aid of an example and with reference to the schematic drawings, in which:

FIG. 1a is a schematic perspective view of an energy harvester according to an embodiment of the invention.

FIG. 1b is a schematic close-up perspective view of the energy harvester shown in FIG. 1a with a top layer removed.

FIG. 2 is a schematic top view of a substrate and a close-up top view of a bonding area on the substrate according to an embodiment of the invention.

FIG. 3 is a cross-sectional side view of an energy harvester according to an embodiment of the invention.

FIG. 4 is a flow diagram of a method for manufacturing an energy harvester according to an embodiment of the invention.

### DETAILED DESCRIPTION

The invention is not limited to the embodiment/s illustrated in the drawings. Accordingly, it should be understood that where features mentioned in the appended claims are followed by reference signs, such signs are included solely for the purpose of enhancing the intelligibility of the claims and are in no way limiting on the scope of the claims.

The term “comprising” as used in this specification and claims means “consisting at least in part of”. When interpreting statements in this specification and claims which include the term “comprising”, other features besides the features prefaced by this term in each statement can also be present. Related terms such as “comprise” and “comprised” are to be interpreted in a similar manner.

The invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

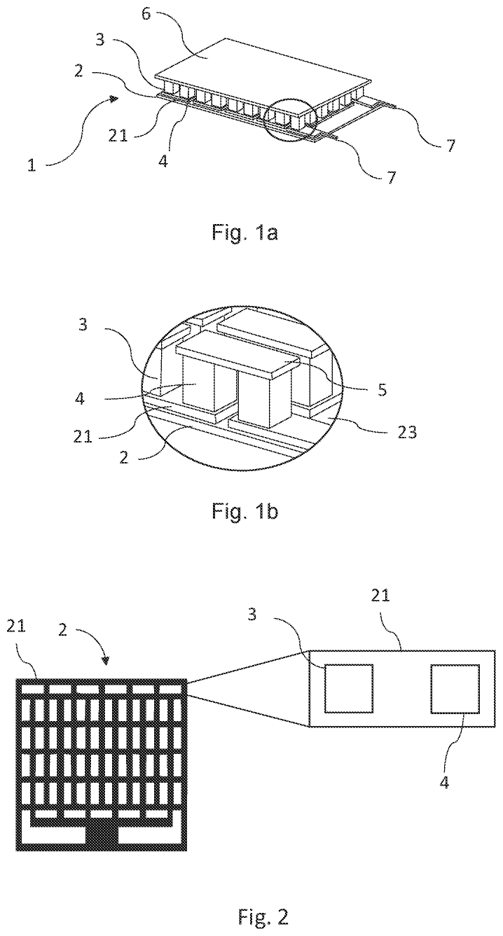

Reference is initially made to FIGS. 1a and 1b which show different schematic perspective views of an energy harvester 1 according to an embodiment of the invention. The energy harvester 1 is for converting thermal energy into electric energy. The energy harvester 1 comprises a substrate 2, a plurality of thermoelectric legs 3, 4, an opposite electrode layer 5, and a top layer 6. The substrate 2 is an electrically conductive and flexible PCB. The substrate 2 comprises a plurality of electrodes 21 deposited on the substrate 2. The plurality of electrodes 21 are deposited on a substrate surface 23. The substrate surface 23 is a planar surface. The plurality of electrodes 21 acts as bonding areas for bonding the thermoelectric legs 3, 4 to the substrate 2. The substrate 2 is formed with a generally box-like shape. During use of the energy harvester 1, the substrate 2 acts as the cold side of the energy harvester 1.

The substrate 2 further comprises two electrical terminals 7 for electrically connecting the energy harvester 1 to an external component, thus allowing the energy harvester to power an external component. The two electrical terminals 7 are formed as two prongs 7 connected in series with the plurality of thermoelectric legs 3, 4.

The plurality of thermoelectric legs 3, 4 comprises a plurality of N-type thermoelectric legs 3 and a plurality of P-type thermoelectric legs 4. The plurality of N-type thermoelectric legs 3 and the plurality of P-type thermoelectric legs 4 each comprise a substrate end for being bonded to the substrate 2 and an opposite end for being bonded to the opposite electrode 5. The thermoelectric legs 3, 4 are arranged on top of the substrate 2 and bonded to the substrate 2 by soldering or sintering. The soldering or sintering of the thermoelectric legs 3, 4 is carried out by depositing a conductive bonding agent onto the electrodes 21 of the substrate 2, thus allowing the thermoelectric legs 3, 4 to be electrically connected to the substrate. The plurality of thermoelectric legs 3, 4 are provided as a plurality of box-shaped pillars. The plurality of thermoelectric legs 3, 4 are arranged in electrically connected pairs, where each pair comprises an N-type thermoelectric leg 3 and a P-type thermoelectric leg 4. The electrically connected pair is electrically connected via being deposited on a same electrode 21 of the substrate 2. The electrodes 21 formed on the substrate 2 are configured for receiving at least two thermoelectric legs 3, 4. The thermoelectrical legs 3, 4 may comprise one or more of the following thermoelectrical materials: MgSb, Mg₃Sb₂, ZnSb, Zn₄Sb₃, Bi₂Te₃, PbTe, and SiGe.

The opposite electrode layer 5 is arranged on the opposite ends of the plurality of N-type thermoelectric legs 3 and the plurality of P-type thermoelectric legs 4. The opposite electrode layer 5 is arranged opposite the substrate 2 relative to the thermoelectric legs 3, 4. The opposite electrode layer 5 is bonded to the plurality of N-type thermoelectric legs 3 and the plurality of P-type thermoelectric legs 4 by soldering or sintering. The opposite electrode layer 5 acts together with the substrate 2 to electrically connect the plurality of N-type thermoelectric legs 3 and the plurality of P-type thermoelectric legs 4 in series with each other. The opposite electrode layer 5 comprises an electrically conductive foil. The opposite electrode layer 5 is preferably provided with a thickness of 100 μm. However, in other embodiments the opposite electrode layer may be as thin as 1 μm or as thick as 500 μm. In the shown embodiment, the opposite electrode layer 5 has been separated into different segments, so it electrically connects the pairs of electrically connected thermoelectric legs 3, 4 in series with each other. During use of the energy harvester 1 the opposite electrode layer 5 acts as the warm side of the energy harvester 1. Consequently, the temperature difference between the warm side, i.e. the opposite electrode layer 5, and the cold side, i.e. the substrate 2, causes the thermoelectric legs 3, 4 to create an electric current via the Seebeck effect. The electrical current created may be delivered to an external component via the electrical terminals 7 connected in series with the thermoelectric legs 3, 4.

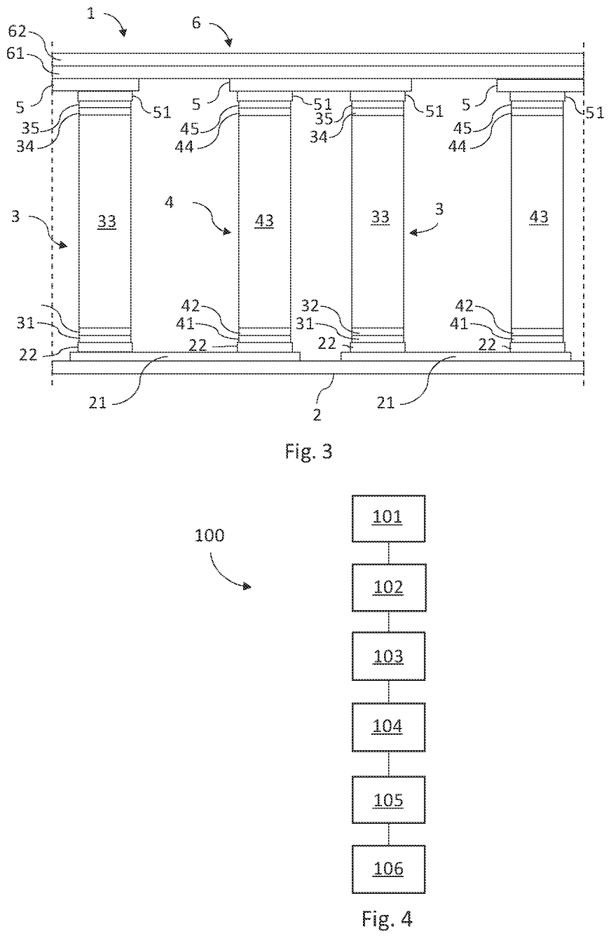

Arranged on the opposite electrode layer is a top layer 6. The top layer 6 is arranged to cover the opposite electrode layer 5 and the thermoelectric legs 3, 4. The top layer 6 will be described in greater detail with reference to FIG. 3.

FIG. 2 shows a schematic top view of a substrate 2 and a close-up top view of a bonding area 21 on the substrate 2 according to an embodiment of the invention. The substrate 2 is arranged in a grid-like structure formed by a plurality of electrodes 21. The plurality of electrodes 21 is formed as rectangular patches on the substrate 2. The electrodes 21 are formed with a width of 4 mm and a length of 1 mm. The electrodes 21 are arranged on the substrate 2 to cooperate with the opposite electrode layer 5 to electrically connect the electrodes 21 in series with each other. The plurality of electrodes 21 are electrically insulated from each other by the substrate 2, consequently, no direct electrical connection is formed in the substrate 2 between the electrodes 21. Each electrode 21 is configured for receiving a pair of thermoelectric legs 3, 4 and electrically connects the associated pair of thermoelectric legs 3, 4. The substrate 2 is a flexible PCB where the plurality of electrodes 21 are provided by a plurality of solder pads on the flexible PCB.

FIG. 3 shows a cross-sectional side view of an energy harvester 1 according to an embodiment of the invention. The substrate 2 is arranged to be the cold side of the energy harvester 1, thus, during use of the energy harvester 1 it is preferable to arrange the energy harvester 1 such that the substrate 2 faces away from any heat sources. The substrate 2 preferably comprises a non-conductive base layer on which a plurality of electrodes 21 are arranged. Each electrode 21 has an N-type thermoelectric leg 3 and P-type thermoelectric leg 4 arranged on it. The electrodes 21 electrically connect the associated thermoelectric legs 3, 4 arranged and bonded to the associated electrode 21. A bonding agent 22 is used to bond the thermoelectric legs 3, 4 to the electrodes 21. The bonding agent 22 may be a solder used for soldering or a sintering powder used for sintering.

Each thermoelectric leg 3, 4 bonded to the electrodes 21 comprises a plurality of layers going from the substrate 2 towards the opposite electrode layer 5. The first layer, starting with the layer closest to the substrate 2, is a first leg electrode 31, 41, the second layer is a first barrier layer 32, 42, the third layer is a thermoelectrical layer 33, 43, the fourth layer is a second barrier layer 34, 44, and the last and fifth layer, closest to the opposite electrode layer 5, is a second leg electrode 35, 45. The first leg electrode 31, 41 acts to electrically connect the thermoelectric leg 3, 4 to the electrode 21 of the substrate 2. The first leg electrode 31, 41 is connected to the electrode 21 via the bonding agent 22. The first barrier layer 32, 42 prevents diffusion of atoms between the first leg electrode 31, 41 and the thermoelectrical layer 33, 43. The thermoelectrical layer 33, 43 is configured to create an electrical current as a result of a temperature difference over the thermoelectrical layer 33, 43. The second barrier layer 34, 44 prevents diffusion of atoms between the second leg electrode 35, 45 and the thermoelectrical layer 33, 43. The second leg electrode 35, 45 acts to electrically connect the thermoelectric leg 3, 4 to the opposite electrode layer 5. The second leg electrode 35, 45 is bonded to the opposite electrode layer 5 via a bonding agent 51. The bonding agent 22 used between the first leg electrode 31, 41 and the electrode 21 of the substrate 2 may be the same type of bonding agent 51 as used between the second leg electrode 35, 45 and the opposite electrode layer 5. The electrode layers 31, 35 for the plurality of N-type thermoelectrical 3 may differ or be the same as the electrode layers 41, 45 for the plurality of P-type thermoelectrical 4. The barrier layers 32, 34 for the plurality of N-type thermoelectrical 3 may differ or be the same as the barrier layers 42, 44 for the plurality of P-type thermoelectrical 4.

The opposite electrode layer 5 acts to electrically connect thermoelectric leg pairs from different electrodes 21 in series with each other. The opposite electrode layer 5 comprises a flexible and conductive foil. The opposite electrode layer 5 is formed as segments extending from an N-type thermoelectric leg 3 on one electrode 21 to a P-type thermoelectric leg 4 arranged on a different electrode 21, thus electrically connecting different thermoelectric leg pairs from different electrodes 21 with each other.

Arranged on the opposite electrode layer 5 opposite the thermoelectric legs 3, 4 is a top layer 6. The top layer 6 comprises an insulating layer 61. The top layer 6 further comprises a thermally conductive base layer 62. The insulating layer 61 acts to insulate the opposite electrode layer 5 from the thermally conductive base layer 62. The insulating layer 61 is provided as a spray-on Boron Nitride layer on the thermally conductive base layer 62.

FIG. 4 shows a flow diagram of a method 100 for manufacturing an energy harvester 1 according to an embodiment of the invention. The method 100 comprises a first step 101 of providing a substrate, wherein the substrate is electrically conductive and flexible. The method 100 comprises a second step 102 of arranging a plurality of N-type thermoelectric legs and a plurality of P-type thermoelectric legs on top of the substrate. The second step 102 may be carried out by a pick-and-place process, e.g. by pick-and-place machinery configured for surface mounted devices. The method 100 comprises a third step 103 of bonding the plurality of N-type thermoelectric legs and the plurality of P-type thermoelectric legs to the substrate. The third step 103 may be carried out by soldering or sintering the thermoelectric legs to the substrate. The method 100 comprises a fourth step 104 of arranging an opposite electrode layer on the plurality of N-type thermoelectric legs and the plurality of P-type thermoelectric legs opposite the substrate. The method 100 comprises a fifth step 105 of bonding the plurality of N-type thermoelectric legs and the plurality of P-type thermoelectric legs to the opposite electrode layer. The fifth step 105 may be carried out by soldering or sintering the thermoelectric legs to the opposite electrode layer. The method 100 comprises a sixth step 106 of separating the opposite electrode layer to electrically connect the plurality of N-type thermoelectric legs and the plurality of P-type thermoelectric legs in series with other. The sixth step 106 may be carried out by cutting the opposite electrode layer, e.g. by laser cutting or blade cutting. The method 100 may further comprise the step of arranging an insulating layer onto the opposite electrode layer opposite the plurality of N-type thermoelectric legs and the plurality of P-type thermoelectric legs. The insulating layer may be provided on a thermally conductive base layer.

Specific embodiments of the invention have now been described. However, several alternatives are possible, as would be apparent for someone skilled in the art.

### REFERENCE SIGNS LIST

1 Energy harvester
2 Substrate
3,4 Thermoelectric legs
5 Opposite electrode layer
6 Top layer
21 Electrodes
23 Substrate surface
7 Electrical terminals
22 Bonding agent
32,42 First barrier layer
33,43 Thermoelectrical layer
34,44 Second barrier layer
35,45 Second leg electrode
31,41 First leg electrode
51 Bonding agent
61 Insulating layer
62 Thermally conductive base layer
100 Method
101 First step of the method
102 Second step of the method
103 Third step of the method
104 Fourth step of the method
105 Fifth step of the method
106 Sixth step of the method

1. A method of manufacturing an energy harvester, the method comprising the steps of:
providing an electrically conductive and flexible substrate having a substrate surface,
providing a plurality of thermoelectric legs each having a substrate end and an opposite end, the plurality of thermoelectric legs comprising N-type thermoelectric legs and P-type thermoelectric legs,
arranging the substrate ends of the plurality of thermoelectric legs on the substrate surface,
bonding the substrate ends of the plurality of thermoelectric legs to the substrate to form a plurality of pairs of neighbouring thermoelectric legs, with each pair of neighbouring thermoelectric legs having an N-type thermoelectric leg being electrically connected to a P-type thermoelectric leg via the substrate ends of the N-type thermoelectric leg and the P-type thermoelectric leg,
providing an opposite electrode layer with an opposite electrode layer surface,
arranging the opposite electrode layer on the opposite ends of the plurality of thermoelectric legs,
bonding the opposite ends of the plurality of thermoelectric legs to the opposite electrode layer surface, and
separating the opposite electrode layer into segments to electrically connect pairs of neighbouring N-type thermoelectric legs and P-type thermoelectric legs, thereby forming serial electrical connections between pairs of neighbouring thermoelectric legs.

2. The method for manufacturing an energy harvester according to claim 1, wherein the steps of bonding the plurality of thermoelectric legs to the substrate and/or the opposite electrode layer is carried out by soldering or sintering.

3. The method for manufacturing an energy harvester according to claim 1, wherein the step of separating the opposite electrode layer into several segments comprises cutting the opposite electrode layer.

4. The method for manufacturing an energy harvester according to claim 1, wherein the step of arranging the plurality of thermoelectric legs on the surface of the substrate is carried out by a pick-and-place process.

5. The method for manufacturing an energy harvester according to claim 1, wherein the method further comprises the step of:
arranging an insulating layer onto the opposite electrode layer opposite the plurality of thermoelectric legs.

6. The method for manufacturing an energy harvester according to claim 5, wherein the insulating layer is provided on a thermally conductive base layer.

7. An energy harvester for converting thermal energy into electric energy, the energy harvester comprising:
an electrically conductive and flexible substrate having a substrate surface,
a plurality of thermoelectric legs each having a substrate end and an opposite end, the thermoelectric legs being arranged on and bonded to the substrate surface by soldering or sintering, and comprising N-type thermoelectric legs and P-type thermoelectric legs, and
an opposite electrode layer arranged on the opposite ends of the plurality of thermoelectric legs and bonded to the plurality of thermoelectric legs by soldering or sintering,
wherein the bonding to the substrate and to the opposite electrode layer provides a serial electrical connection of alternating N-type thermoelectric legs and P-type thermoelectric legs.

8. The energy harvester according to claim 7, wherein the substrate comprises a flexible circuit board, CB.

9. The energy harvester according to claim 7, wherein the opposite electrode layer comprises an electrically conductive foil.

10. The energy harvester according to any of claim 7, wherein the serial electrical connection of alternating N-type thermoelectric legs and P-type thermoelectric legs comprises individual N-type thermoelectric legs serially connected to groups of P-type thermoelectric legs, individual P-type thermoelectric legs serially connected to groups of N-type thermoelectric legs or groups of N-type thermoelectric legs serially connected to groups of P-type thermoelectric legs.

11. The energy harvester according to claim 7, wherein the energy harvester does not comprise a further layer arranged onto the opposite electrode layer opposite the plurality of thermoelectric legs.

12. The energy harvester according to claim 7, wherein the energy harvester is obtainable in a method comprising the steps of:
providing an electrically conductive and flexible substrate having a substrate surface.
providing a plurality of thermoelectric legs each having a substrate end and an opposite end, the plurality of thermoelectric legs comprising N-type thermoelectric legs and P-type thermoelectric legs,
arranging the substrate ends of the plurality of thermoelectric legs on the substrate surface,
bonding the substrate ends of the plurality of thermoelectric legs to the substrate to form a plurality of pairs of neighbouring thermoelectric legs, with each pair of neighbouring thermoelectric legs having an N-type thermoelectric leg being electrically connected to a P-type thermoelectric leg via the substrate ends of the N-type thermoelectric leg and the P-type thermoelectric leg,
providing an opposite electrode layer with an opposite electrode layer surface.
arranging the opposite electrode layer on the opposite ends of the plurality of thermoelectric legs.
bonding the opposite ends of the plurality of thermoelectric legs to the opposite electrode layer surface, and
separating the opposite electrode layer into segments to electrically connect pairs of neighbouring N-type thermoelectric legs and P-type thermoelectric legs, thereby forming serial electrical connections between pairs of neighbouring thermoelectric legs.

13. The energy harvester according to claim 9. wherein the electrically conductive foil has a thickness in the range of 1 μm to 500 μm.
